(19) United States
(12) Patent Application Publication
(10) Pub. No.: US 2002/0001906 A1
(43) Pub. Date: Jan. 3, 2002

(54) Method of manufacturing a gate in a semiconductor device

(76) Inventor: Dae Gyu Park, Kyungki-Do (KR)

Correspondence Address: MARSHALL, O'TOOLE, GERSTEIN, MURRAY & BORUN, 6300 SEARS TOWER, 233 SOUTH WACKER DRIVE, CHICAGO, IL, 60606-6402, US

(21) Appl. No.: 09/882,103

(22) Filed: Jun. 15, 2001

(30) Foreign Application Priority Data
Jun. 27, 2000 (KR) 2000-35691

(51) Int. Cl. H01L 21/336; H01L 21/3205; H01L 21/4763

(52) U.S. Cl. 438/287; 438/591; 438/585

(57) ABSTRACT

A method of manufacturing a gate in a semiconductor device is disclosed. The method forms a TiAlN film as a barrier layer between a gate insulating film and a metal gate by CVD method or PVD method resulting in the prevention of a leakage current and the obtaining of a low threshold voltage.

### BACKGROUND OF THE INVENTION

1. Field of the Invention

The invention relates generally to a method of manufacturing a gate in a semiconductor device. More particularly, the invention relates to a method of manufacturing a gate in a semiconductor device, which can prevent a gate leakage current and obtain a low threshold voltage, by forming a TiAlN film between a gate insulating film and a metal gate.

2. Description of the Prior Art

In the process of manufacturing DRAMs and logic devices, etc., which have been mass-produced, a silicon oxide (SiO₂) film has been widely used as a gate insulating film. As the design rule is reduced, however, it has become apparent that the thickness of the silicon oxide film to be formed cannot be reduced below the range of 25 Å to 30 Å because of a tunneling limit. For example, in a design rule of 0.1, the thickness of the gate insulating film is expected to be in the range of 25 Å to 30 Å. Due to increase in an off-current by a direct tunneling, however, there is a possibility that it may adversely affect the operation of a device. In particular, in case of a memory device, there is a need for a method of reducing a leakage current. For this, a study has been made in which an insulating material having a high dielectric constant is used.

For example, a tantalum oxide film (Ta₂O₅), a titanium oxide film (TiO₂), an aluminum oxide film (Al₂O₃), etc., which are used as a dielectric film of a capacitor, are used as the gate insulating film. The aluminum oxide film (Al₂O₃) has more than 2.5 times the dielectric constant than the silicon oxide film. As the integration degree of a semiconductor device increases, however, when the thickness is formed in the range of 25 Å to 30 Å, there is a possibility that its application is problematic because the value of the dielectric constant is lowered as the thickness is reduced. In order to overcome this problem, if metal is used as the gate material instead of polysilicon, an insulating film having a thickness in the range of 25 Å to 30 Å can be formed without significant problems.

However, in case where the gate is formed with a W/WN or W/TiN structure, if it is combined with an aluminum oxide film or a tantalum oxide film having an effective charge of −2 to 3×10¹²/cm², because the work function of the gate ranges from 4.55 to 4.8 eV, there is a possibility that the following problem may occur. Specifically, as the flat band voltage in the capacitor ranges from 0.2 to 0.3V and the threshold voltage ranges from 1.0 to 1.1V, being greater about 0.5V as compared the 0.4 to 0.6V ranges which is necessary in the level of a sub-micron device, it will be difficult to apply it to a metal gate structure and an insulating film structure having a high dielectric constant.

### SUMMARY OF THE DISCLOSED METHOD

A method of manufacturing a gate in a semiconductor device capable of preventing a leakage current in the process of manufacturing a high-integration high-speed device is disclosed.

A method of manufacturing a gate in a semiconductor device capable of obtaining a low threshold voltage in the process of manufacture a high-integration high-speed device is disclosed.

A method of manufacturing a gate in a semiconductor device capable of improving reliability of a high-integration high-speed device is also disclosed.

The disclosed method of manufacturing a gate in a semiconductor device comprises the steps of forming a gate insulating film and a TiAlN film on a semiconductor substrate, forming a metal layer and an insulating film on the TiAlN film, patterning the insulating film, and then etching the metal layer, the TiAlN film and the gate insulating film using the patterned insulating film as a mask, thus forming a gate, and removing the insulating film.

### BRIEF DESCRIPTION OF THE DRAWINGS

The disclosed method will be explained in the following description, taken in conjunction with the accompanying drawings, wherein:

FIGS. 1A and 1B are cross-sectional view of explaining a method of manufacturing a gate in a semiconductor device.

### DETAILED DESCRIPTION OF PRESENTLY PREFERRED EMBODIMENTS

In the disclosed method, a TiAlN film as a barrier layer is formed between a gate insulting film and a metal gate. As the TiAlN film is formed by PVD method or CVD method, the work function of the TiAlN film is reduced compared to that of a TiN film. Therefore, a low threshold voltage can be obtained in a gate insulating film having a high dielectric constant such as Al₂O₃ or Ta₂O₅ having a negative effective charge. This employs the characteristic in which, in case of a TiAlN film having a solid solution characteristic of TiN and AlN, AlN having a wide band gap (˜5 eV) and electron affinity ranging from about 1.5 to about 2 eV is added to form a barrier layer having a metal characteristic, and the work function at this time is reduced compared to that of TiN. Also, the TiAlN film has an advantage since it has a good oxidization-resistant compared to TiN.

The disclosed method will be described in detail by way of a preferred embodiment with reference to accompanying drawings.

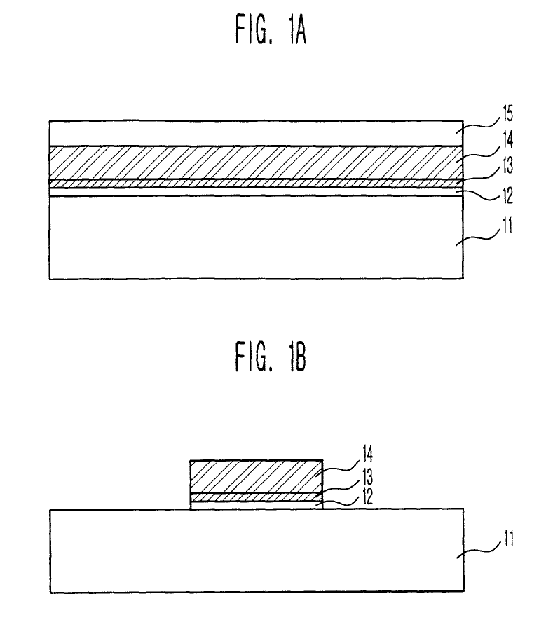

Referring now to FIGS. 1A and 1B, a method of manufacturing a gate in a semiconductor device will be explained.

FIG. 1A shows a cross-sectional view of a device in which a gate insulating film 12, a TiAlN film 13, a metal layer 14 and an insulating film 15 are sequentially formed on a semiconductor substrate 11.

The gate insulating film 12 is formed in thickness ranging from about 3 Å to about 20 Å using a silicon oxide film or an oxide film having a high dielectric constant. The silicon oxide film is formed by means of a thermal oxidization process at a temperature ranging from about 600° C. to about 900° C. The oxide film having a high dielectric constant may employ a Al₂O₃ film, a Ta₂O₅ film, a TiO₂ film, a ZrO₂ film, a HfO₂ film, a mixture oxide film of 3-elements series such as ZrAlO, HfAlO, ZrSiO₄, HfSiO₄, etc. Also, before the oxide film having a high dielectric constant is formed, a silicon oxide film may be formed in thickness ranging from about 3 Å to about 10 Å. Meanwhile, in order to improve the characteristic of the oxide film having a high dielectric constant, a rapid thermal process in the temperature ranging from about 500° C. to about 800° C. for a time period ranging from about 10 seconds to about 5 minutes, a thermal process ranging from about 10 seconds to about 100 minutes or a UV/O₃ process may be performed.

The TiAlN film 13 may be formed through the process by which N₂ at a flow rate ranging from about 15 sccm to about 80 sccm and Ar at a flow rate ranging from about 5 sccm to about 25 sccm are implanted, a target of TiAlₓ (x=0.05˜0.35) is mounted into the chamber keeping the temperature therein in the range from about −30° C. to about 500° C. and a power ranging from about 500 W to about 7 kW is then applied, or the process by which a target of TiAlN (AlN=0.05˜0.35) is mounted under inert gases such as Ar, Xe, Kr, etc., and a DC or a RF bias is applied. Also, the TiAlN film 13 is formed using a CVD method, using TiCl₄ and TDMAT as a source material of Ti, AlCl₃, TMA[Al(CH₃)₃] as a source material of Al, and NH₃, ND₃ and N₃ as a source material of N so that the composition of AlN can range from about 5% to about 35%. Also, the CVD deposition may be performed by means of thermal nitrification method at the temperature ranging from about 450° C. to about 700° C.

Meanwhile, the TiAlN film 13 may be deposited by means of ALD (atomic layer deposition) method. For this, with the substrate is kept at a temperature ranging from about 150° C. to about 450° C., after a Ti source is added, a nitrogen source is added to deposit a TiN and after an Al source is added, a nitrogen source is added to deposit AlN. At this time, the composition ratio of AlN within the thin film is determined by the number of addition of AlN to the total number of addition.

After the TiAlN film 13 is formed, a rapid thermal oxidization process is performed in order to increase oxidization resistance within the thin film, which uses a rapid thermal process and is performed for about 10 to about 30 seconds when it is ramped up to the temperature ranging from about 500° C. to about 650° C. under an oxygen atmosphere. At this time, oxygen is mainly collected at the grain boundary within the thin film and the total amount of oxygen ranges from about 1% to about 3%.

The metal layer 14 is formed of any one of a W film, a Ta film, a WN film, a TaN film, an Al film, a TiSix film, a CoSix film and a NiSi film and is formed in thickness ranging from about 500 Å to about 1500 Å.

The insulating film 15 is formed of a SiO2 film, a Si3N4 film or a SiON film and is formed in thickness ranging from about 300 Å to about 2000 Å.

Referring now to FIG. 1B, after the insulating film 15 is patterned, the metal layer 14, the TiAlN film 13 and the gate insulating film 12 are sequentially etched and patterned using the patterned insulating film 15 as a mask. Then, the patterned insulating film 15 is removed to form a gate.

As mentioned above, the present invention can obtain a low threshold voltage while preventing generating a leakage current by forming a TiAlN film between a gate insulating film and a metal gate. Thus, it can improve reliability of a high-integration high-speed device.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed:

1. A method of manufacturing a gate in a semiconductor device, comprising the steps of:
forming a gate insulating film on a semiconductor substrate;
forming a TiAlN film on the gate insulating film;
forming a metal layer on the TiAIN film;
forming an insulating film on the metal layer;
patterning the insulating film to expose at least part of the metal layer;
etching the exposed part of said metal layer, said TiAlN film and said gate insulating film using said patterned insulating film as a mask thereby forming a gate; and
removing said insulating film.

2. The method of manufacturing a gate in a semiconductor device according to claim 1, wherein said gate insulating film is formed of a silicon oxide film or an oxide film having a high dielectric constant.

3. The method of manufacturing a gate in a semiconductor device according to claim 2, wherein the gate insulating film is an oxide film having a high dielectric constant and said oxide film having a high dielectric constant is selected from the group consisting of a Al₂O₃ film, a Ta₂O₅ film, a TiO₂ film, a ZrO₂ film, a HfO₂ film, a ZrAlO film, a HfAlO film, a ZrSiO₄ film and a HfSiO₄ film.

4. The method of manufacturing a gate in a semiconductor device according to claim 2, wherein the gate insulating film is an oxide film having a high dielectric constant and before said oxide film having a high dielectric constant is formed as said gate insulating film, a silicon oxide film is formed on the substrate having thickness ranging from about 3 Å to about 10 Å.

5. The method of manufacturing a gate in a semiconductor device according to claim 1, wherein the gate insulating film is an oxide film having a high dielectric constant and after said oxide film having a high dielectric constant is formed as said gate insulating film, a rapid thermal process at a temperature ranging from about 500° C. to about 800° C. for a time period ranging from about 10 seconds to about 5 minutes, a thermal process for a time period ranging from about 10 seconds to about 100 minutes or a UV/O₃ process are performed.

6. The method of manufacturing a gate in a semiconductor device according to claim 1, wherein said TiAlN film is formed by implanting N₂ at a flow rate ranging from about 15 sccm to about 80 sccm and Ar at a flow rate ranging from about 5 sccm to about 25 sccm, and the method further comprises mounting a target of TiAl in a chamber within which the temperature ranging from about −30° C. to about 500° C. is maintained and then applying power at a voltage ranging from about 500 W to about 7 kW.

7. The method of manufacturing a gate in a semiconductor device according to claim 6, wherein in said TiAl target, the composition of Al ranges from about 5% to about 35%.

8. The method of manufacturing a gate in a semiconductor device according to claim 1, wherein said TiAlN film is formed by mounting a target of TiAlN in a chamber filled with inert gases and then applying a DC or a RF bias.

9. The method of manufacturing a gate in a semiconductor device according to claim 8, wherein in said TiAl target, the composition of AlN ranges from about 5% to about 35%.

10. The method of manufacturing a gate in a semiconductor device according to claim 1, wherein said TiAlN film is formed by using TiCl4 and TDMAT as a source material of Ti, using AlCl₃ and TMA [Al(CH₃)₃] as a source material of Al, and using NH₃, ND₃ and N₃ as a source material of N so that the composition of AlN ranges from about 5% to about 35%.

11. The method of manufacturing a gate in a semiconductor device according to claim 1, wherein the TiAIN film is formed by atomic layer deposition by maintaining said substrate at a temperature ranging from about 150° C. to about 450° C.,
adding a Ti source,
adding a nitrogen source to deposit TiN,
adding an Al source, and
adding a nitrogen source to deposit AlN.

12. The method of manufacturing a gate in a semiconductor device according to claim 1, wherein after said TiAlN film is formed, a rapid thermal oxidization process is performed.

13. The method of manufacturing a gate in a semiconductor device according to claim 12, wherein said rapid thermal oxidization process is performed for a time period ranging from about 10 seconds to about 30 seconds at a temperature ranging from about 500° C. to about 650° C. under an oxygen atmosphere.

14. The method of manufacturing a gate in a semiconductor device according to claim 1, wherein said metal layer is selected from the group consisting of a W film, a Ta film, a WN film, a TaN film, an Al film, a TiSix film, a CoSix film and a NiSi film.

15. The method of manufacturing a gate in a semiconductor device according to claim 1, wherein said insulating film is selected from the group consisting of a SiO₂ film, a Si₃N₄ film and a SiON film.

16. A semiconductor device comprising a gate and being manufactured in accordance with the method of claim 1.
